(19) United States
(12) Patent Application Publication
(10) Pub. No.: US 2010/0202182 A1
(43) Pub. Date: Aug. 12, 2010

(54) MEMORY DEVICES, SYSTEMS AND METHODS USING MULTIPLE 1/N PAGE ARRAYS AND MULTIPLE WRITE/READ CIRCUITS

(75) Inventors: Sang Beom Kang, Hwasung-si (KR); Ho Jung Kim, Suwon-si (KR); Chul Woo Park, Yongin-si (KR); Jung Min Lee, Suwon-si (KR); Hyun Ho Choi, Suwon-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/700,882

(22) Filed: Feb. 5, 2010

(30) Foreign Application Priority Data
Feb. 11, 2009 (KR) 10-2009-0010931

(51) Int. Cl. G11C 5/06; G11C 11/00; G11C 7/00; G11C 7/10

(52) U.S. Cl. 365/63; 365/148; 365/189.14; 365/189.04

(57) ABSTRACT

A memory device architecture includes N arrays respectively for storing a 1/N of a page and N write/read circuits, where N is a natural number, respectively for writing or reading a 1/N of the page to/from each of the N arrays.

### CROSS-REFERENCE TO RELATED APPLICATION

This application claims priority under 35 U.S.C. §119 to Korean Patent Application No. 10-2009-0010931, filed on 11 Feb., 2009, in the Korean Intellectual Property Office, the disclosure of which is incorporated herein in its entirety by reference.

### BACKGROUND

Embodiments of the present inventive concept relate to integrated circuit memory devices, and more particularly, to memory core architectures for memory devices, memory systems including the memory devices, and methods of processing data thereof.

Since a memory device processes, e.g., writes and/or reads, a lot of data at once, a large number of sense amplifiers and write drivers are generally used. Therefore, sense amplifiers and write drivers may occupy a large portion of the area of a memory device.

### SUMMARY

The present general inventive concept provides memory core architectures for memory devices, memory systems, and methods for processing data thereof.

Memory devices according to various embodiments of the present invention include N arrays, a respective of which is configured to store 1/N of a page. N write/read circuits are also provided, where N is a natural number, a respective one of which is adjacent a respective one of the N arrays and is configured to write/read the 1/N of the page to/from the adjacent one of the N arrays. In some embodiments, the memory device includes a semiconductor substrate, wherein the N arrays and the N write/read circuits are arranged in the semiconductor substrate to provide an integrated circuit memory device. In other embodiments, the memory device further includes a second group of N arrays arranged in the semiconductor substrate, a respective one of which is configured to store 1/N of a page. A second group of N write/read circuits is also provided, a respective one of which is adjacent a respective one of the N arrays in the second group, and is configured to write/read the 1/N of the page to/from the adjacent one of the N arrays.

According to other embodiments, the N arrays are separated each other and arranged respectively, and the N write/read circuits are arranged in a word line direction on a side of each of the N arrays, respectively. According to other embodiments, the N arrays are enabled at the same time or sequentially, respectively, and the N write/read circuits are enabled at the same time or sequentially, respectively. According to other embodiments, the N arrays are enabled by M arrays, where M is a natural number and smaller than N, and the N write/read circuits are enabled by M write/read circuits.

The N arrays may include a plurality of non-volatile memory cells, e.g., a plurality of resistive memory cells, respectively. The N may be determined by a value calculated by a dividing a density of the memory device by a density of the N arrays. The N arrays may be arranged in a two-dimensional matrix form and the N write/read circuits may be arranged in a first direction on a side of each of the N arrays, respectively.

The memory device may further include a plurality of first data buses, a respective one of which is connected to a respective plurality of write/read circuits arranged in the first direction, a second data bus arranged in a second direction which is perpendicular to the first direction, and a plurality of switching circuits, a respective one of which is connected between respective one of the first data buses and the second data bus.

The plurality of switching circuits may connect each of the plurality of first data buses to the second data bus successively in response to a corresponding switching signal among a plurality of switching signals, respectively.

According to some embodiments, the second data bus may be routed over a plurality of arrays arranged in the second direction. According to other embodiments, the second data bus may be routed on a side of a plurality of arrays arranged in the second direction.

Other embodiments of the present invention are directed to a memory device, including N arrays respectively including a plurality of word lines, a plurality of bit lines, and a plurality of non-volatile memory cells connected between the plurality of word lines and the plurality of bit lines, and N write/read circuits, a respective one of which is connected to a respective one of the N non-volatile memory arrays. The number of the plurality of bit lines connected to each of the N write/read circuits corresponds to a value calculated by dividing a page of the memory device by N. The memory device may include a semiconductor substrate, and multiple groups of arrays and write/read circuits may be provided as was described above.

The N arrays may be arranged in a two-dimensional matrix form and the memory device may further include a plurality of first data buses, a respective one of which is connected to a respective one of a plurality of write/read circuits arranged in a first direction, a second data bus arranged in a second direction which is perpendicular to the first direction, and a plurality of switching circuits, a respective one of which is connected between a respective one of the plurality of first data buses and the second data bus.

Other embodiments of the present invention are directed to a memory system, including a memory device and a processor connected to the memory and controlling writing or reading a page to/from the memory by a page.

The memory device includes N arrays, a respective of which is configured to store 1/N of a page. N write/read circuits are also provided, where N is a natural number, a respective one of which is adjacent a respective one of the N arrays and is configured to write/read the 1/N of the page to/from the adjacent one of the N arrays. In some embodiments, the memory device includes a semiconductor substrate, wherein the N arrays and the N write/read circuits are arranged in the semiconductor substrate, to provide an integrated circuit memory device. In other embodiments, the memory device further includes a second group of N arrays arranged in the semiconductor substrate, a respective one of which is configured to store 1/N of a page. A second group of N write/read circuits is also provided, a respective one of which is adjacent a respective one of the N arrays in the second group, and is configured to write/read the 1/N of the page to/from the adjacent one of the N arrays.

Other embodiments of the present invention are directed to a memory system, including a memory device, a processor connected to the memory device and controlling writing or reading a page to/from the memory device by page.

The memory device includes N arrays respectively including a plurality of word lines, a plurality of bit lines, and a plurality of non-volatile memory cells connected between the plurality of word lines and the plurality of bit lines, and N write/read circuits, a respective one of which is connected to a respective one of the N non-volatile memory arrays. The number of the plurality of bit lines connected to each of the N write/read circuits corresponds to a value calculated by dividing the page of the memory device by the N. The memory device may include a semiconductor substrate, and multiple groups of arrays and write/read circuits may be provided as was described above.

Other embodiments of the present invention are directed to a data processing method of a data processing device, including reading 1/N of a page from each of N arrays storing the 1/N of the page by using each of N read circuits and transmitting the 1/N of the page read by each of the N read circuits to a data bus successively to output the page.

Other embodiments of the present invention are directed to a data processing method of a data processing device, including receiving, by each of N write circuits, 1/N of a page and writing, by each of the N write circuits, the 1/N of the page to each of N arrays.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 shows a block diagram of a memory device according to various embodiments of the present invention;

FIG. 2 shows a circuit diagram of a write/read circuit illustrated in FIG. 1;

FIG. 3 shows a circuit diagram of a first switching circuit illustrated in FIG. 1;

FIG. 4 shows a block diagram of a memory device according to other embodiments of the present invention;

FIG. 5 shows a block diagram of a memory device according to other embodiments of the present invention;

FIG. 6 shows a block diagram of a memory device according to other embodiments of the present invention;

FIG. 7 show a block diagram of a memory device according to other embodiments of the present invention;

FIG. 8 shows a block diagram of a memory system including a memory device according to various embodiments of the present invention;

FIG. 9 shows a data processing method of a data processing device according to various embodiments of the present invention; and

FIG. 10 shows a data processing method of a data processing device according to other embodiments of the present invention.

### DETAILED DESCRIPTION OF THE PREFERRED EMBODIMENTS

The present invention now will be described more fully hereinafter with reference to the accompanying drawings, in which various embodiments are shown. However, this invention should not be construed as limited to the embodiments set forth herein. Rather, these embodiments are provided so that this disclosure will be thorough and complete, and will fully convey the scope of the invention to those skilled in the art. In the drawings, the relative sizes of regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element is referred to as being “connected”, “coupled” or “responsive” to another element (or variations thereof), it can be directly connected, coupled or responsive to the other element or intervening elements may be present. In contrast, when an element is referred to as being “directly connected”, “directly coupled” or “directly responsive” to another element (or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, the terms “horizontal” and “vertical” are used to refer to two relative orthogonal directions, but do not imply a specific orientation.

Embodiments of the present invention are described herein with reference to cross section and perspective illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

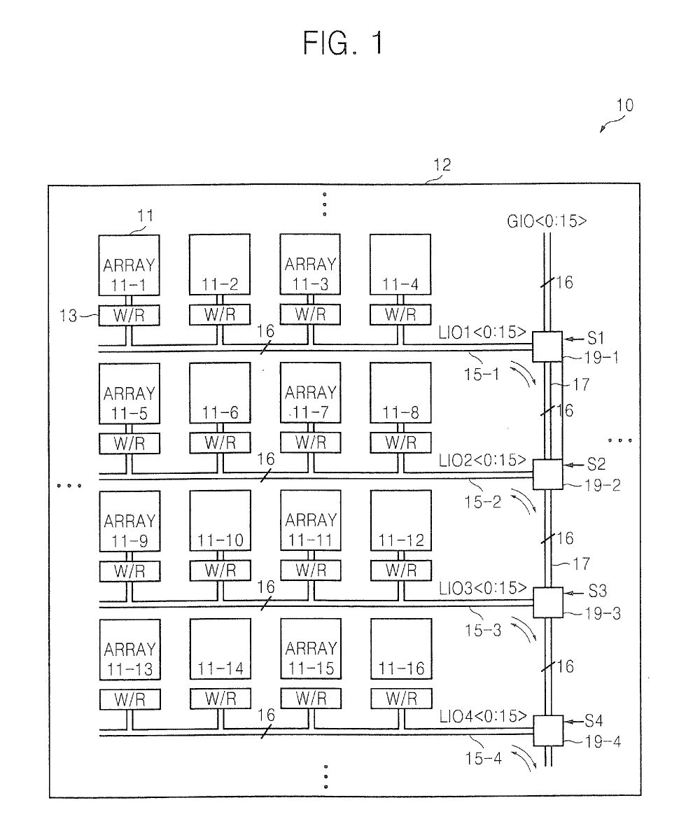

FIG. 1 shows a block diagram of a memory device according to various embodiments of the present invention. A core architecture of a memory device is illustrated in FIG. 1. Referring to FIG. 1, a memory device 10 may include N arrays 11 and N write/read circuits 13. Here, N is a natural number. In addition, the memory device 10 may further include a plurality of first data buses 15-1˜15-4, a plurality of switching circuits 19-1˜19-4, and a second data bus 17. In some embodiments, the elements of the memory device 10 are all integrated in a semiconductor integrated circuit substrate 12, also referred to as a “chip”. Moreover, as illustrated by the three dots ( . . . ) along each direction of the substrate 12, the elements of the memory device 10 may be replicated in the semiconductor integrated circuit substrate 12 along any or all directions thereof, to provide two or more groups of the elements illustrated herein.

The N arrays 11 include a plurality of word lines, a plurality of bit lines, and a plurality of non-volatile memory cells connected between the plurality of word lines and the plurality of bit lines, respectively. The plurality of non-volatile memory cells may be embodied as storage-oriented resistive memory cells, respectively. According to some embodiments, the plurality of non-volatile memory cells may be embodied as Magnetic RAM (MRAM), Ferroelectric RAM (FeRAM), Resistive RAM (ReRAM), and/or Phase-change RAM (PRAM).

The N arrays 11 may store a 1/N of a page respectively. Here, a 1/N of a page is called a portion. For example, one page may be 512 Bytes, 1 KBytes, 2 KBytes, or 4 KBytes. That is, the one page may be a multiple of 512 Byte. According to some embodiments, N arrays 11 all may be enabled simultaneously. Additionally, according to other embodiments, they may be enabled by units of row at the same time to reduce power consumption. For example, a plurality of arrays may be arranged in a row.

Read active time, which is taken to enable all of N arrays 11 simultaneously or by units of row, can be shorter than read active time, which is taken to enable each of the N arrays 11 one by one. During a write operation, N write/read circuits 13 may write each portion configuring one page to a corresponding array among the N arrays 11, respectively.

Additionally, during a read operation, N write/read circuits 13 may transmit each portion read from each of the N arrays 11 to each of first data buses 15-1 to 15-4 respectively. The N write/read circuits 13 may be arranged on a side of each of the N arrays 11, respectively. For example, the N write/read circuits 13 may be embodied in a word line direction, respectively. The N write/read circuits 13 may also be connected to a plurality of bit lines, respectively.

For an ease of explanation, FIG. 1 illustrates 16 arrays 11, 16 write/read circuits 13, four first data buses 15-1 to 15-4, 4 switching circuits 19-1 to 19-4, and a second data bus 17. For example, the four first data buses 15-1 to 15-4 may have 16-bit width and be called local input/output lines, respectively. In addition, a second data bus 17 may have 16-bit width and be called a global input/output lines. However, larger or smaller numbers of any or all of these elements may be provided, and the structures may be replicated along any or all directions.

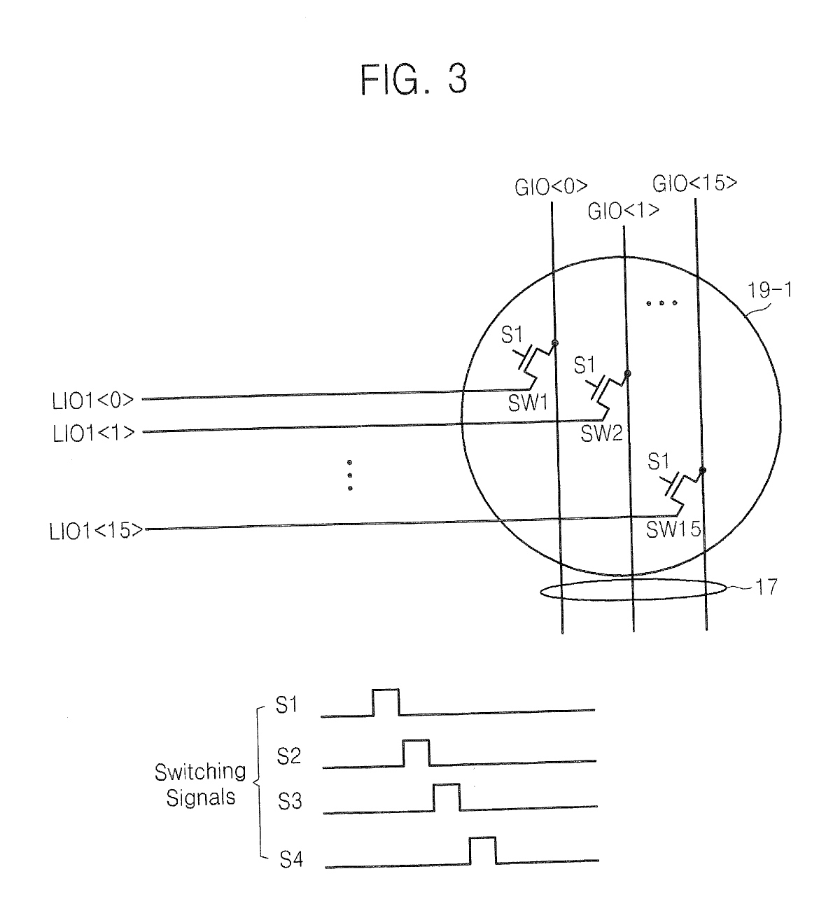

Four switching circuits 19-1 to 19-4 during a read operation may transmit each data of the four first data buses 15-1 to 15-4 to the second data bus 17 successively in response to each of non-overlapping switching signals S1 to S4 as illustrated in FIG. 3, respectively. The four switching circuits 19-1 to 19-4 during a write operation may also transmit each portion of a page input through the second data bus 17 to each of the four first data buses 15-1 to 15-4 successively in response to each of the non-overlap switching signals S1 to S4 as illustrated in FIG. 3, respectively.

For example, when a chip size or device density of a memory device 10 is D and array size or array density of the array 11 is A, the number NA of arrays embodied in the memory device 10 may be calculated by using an Equation 1.

NA=D/A [Equation 1]

For example, when D is 16 MBytes and A is 1 MByte, NA is 16. 16 arrays 11 may be arranged in a second dimension, e.g., a*b matrix form, and 16 write/read circuits 13 may be arranged at one side of each of the 16 arrays, respectively. Here, a and b are natural numbers, e.g., a=b=4. Additionally, when D is 32 MBytes and A is 1 MByte, NA is 32. Thus, 32 arrays may be arranged in a second dimension, e.g., c*d matrix form, respectively, and 32 write/read circuits may be arranged at one side of each of the 32 arrays. Here, c and d are natural numbers, e.g., c=4 and d=8 or c=8 and d=4. According to embodiments, when 32 arrays are stacked by two, the 32 arrays may be arranged in three-dimensions. The three-dimensional arrangements may use a plurality of stacked semiconductor integrated circuit substrates or a single semiconductor integrated circuit substrate.

The number NA of arrays 11 and the number of write/read circuits 13 embodied in a memory device 10 according to embodiments of the present invention may be the same as each other.

When a page is P Bytes, each size SZ of write/read circuits 13, i.e., an amount of data capable of pre-fetching to write or read at once, may be calculated by using an Equation 2.

SZ=P/NA [Equation 2]

For example, when a page P is 1 KByte and the number NA of arrays embodied in a memory device 10 is 16, each size SZ of write/read circuits is 64 Bytes. Accordingly, 16 arrays 11 may store a 1/16 of the page P respectively and 16 write/read circuits 13 may process, e.g., sense amplifying for reading or driving for writing, a 1/16 of the page P respectively.

A memory device 10 capable of processing data by a page may store a plurality of pages. However, for an ease of explanation, a method of writing or reading a page, which is to be processed, to/from N arrays 11 successively or in a time division method by using N write/read circuits 13 is mainly explained. Such method is effective when random access is required in a page. As another example, when a page P is 2 KBytes and the number of arrays NA embodied in the memory device 10 is 16, each size SZ of write/read circuits 13 is 128 Bytes.

The following explains a read operation referring to FIG. 1.

A first portion of a page, e.g., a 1/16 of a page, read from a first array 11-1 through a first write/read circuit arranged at a first row may be transmitted to a second data bus 17 through a first data bus 15-1 and a first switching circuit 19-1. The first portion of the page transmitted to the second data bus 17 may be transmitted to a peripheral circuit (not shown) or an input/output pad (not shown). A second portion of the page, e.g., a 1/16 of the page, read from a second array 11-2 through a second write/read circuit arranged at a first row may be transmitted to the second data bus 17 through the first data bus 15-1 and the first switching circuit 19-1. The second portion of the page transmitted to the second data bus 17 may be transmitted to a peripheral circuit or a pad.

A third portion and a fourth portion of the page read from a third array 11-3 and a fourth array 11-4 respectively through a third and a fourth write/read circuit arranged at a first row may be transmitted to the second data bus 17 through the first data bus 15-1 and the first switching circuit 19-1 successively or in a time-division method. The third and the fourth portion of the page transmitted to the second data bus 17 may be transmitted to a peripheral circuit or a pad, respectively.

After a read operation for a first row is completed, each portion of a page read successively from each array 11-5 to 11-8 through each write/read circuit arranged at a second row may be transmitted to the second data bus 17 successively through the first data bus 15-1 and a second switching circuit 19-2. After a read operation for a second row is completed, each portion of a page read successively from each array 11-9 to 11-12 through each write/read circuit arranged at a third row may be transmitted to the second data bus 17 successively through the first data bus 15-1 and a third switching circuit 19-3.

Lastly, after a read operation for a third row is completed, each portion of a page read successively from each array 11-13 to 11-16 through each write/read circuit arranged at a fourth row may be transmitted to the second data bus 17 successively through the first data bus 15-1 and a fourth switching circuit 19-4. That is, each portion of a page read from each array 11-1 to 11-16 successively may be transmitted to the second data bus 17 successively through each of the first data bus 15-1 to 15-4. Later, a memory device 10 may form a page by combining each portion and transmit a formed page to an external device by page.

Continuing, the following explains a write operation referring to FIG. 1.

Each portion of a page input from outside may be transmitted to the second data bus 17 successively.

A first portion of a page, e.g., a 1/16 of a page, may be transmitted from the second data bus 17 to the first data bus 15-1 by a switching operation of a first switch 19-1. A first write/read circuit of a first row connected to the first data bus 15-1 may receive a first portion of a page and write a received first portion to a first array 11-1. Continuously, a second portion of the page may be transmitted from the second data bus 17 to the first data bus 15-1 by a switching operation of the first switch 19-1. A second write/read circuit of a first row connected to the first data bus 15-1 may receive a second portion of the page and write it to a second array 11-2.

Additionally, a third portion of the page may be transmitted from the second data bus 17 to the first data bus 15-1 by a switching operation of the first switch 19-1. A third write/read circuit of a first row connected to the first data bus 15-1 may receive the third portion of the page and write it to a third array 11-3. Continuously, a fourth portion of the page may be transmitted from the second data bus 17 to the first data bus 15-1 by a switching operation of the first switch 19-1. A fourth write/read circuit connected to the first data bus 15-1 may receive the fourth portion of the page and write it to a fourth array 11-4.

After a write operation for a first row is completed, a second switching circuit 19-2 may transmit a fifth portion to an eighth portion of the page to a first data bus 15-2 routed at a second row successively in response to a second switching signal S2. Accordingly, each write/read circuit of a second row may write each portion of the page successively input through the second switching circuit 19-2 and the first data bus 15-2 to each array 11-5 to 11-8 successively.

After a write operation for a second row is completed, a third switching circuit 19-3 may transmit a ninth to a twelfth portion of the page successively to a first data bus 15-3 routed at a third row in response to a third switching signal S3. Accordingly, each write/read circuit arranged at a third row may write each portion of the page successively input through the third switching circuit 19-3 and the first data bus 15-3 to each array 11-9 to 11-12 successively.

After a write operation for a third row is completed, a fourth switching circuit 19-4 may transmit a thirteenth to a sixteenth portion of the page to a first data bus 15-4 routed at a fourth row successively in response to a fourth switching signal S4. Accordingly, each write/read circuit arranged at a fourth row may write each portion of the page successively input through the fourth switching circuit 19-4 and the first data bus 15-4 to each array 11-13 to 11-16 successively.

The above explained a case that each portion of the page is successively written to each array 11-1 to 11-16 or each portion of the page stored in each array 11-1 to 11-16 is successively read. However, a memory device 10 according to various embodiments may write or read each portion of the page to/from each array 11-1 to 11-16 randomly by controlling on/off timing of each switching signal S1 to S4 of each switching circuit 19-1 to 19-4 appropriately.

Accordingly, a memory device 10 according to various embodiments of the present invention may further include a timing controller (not shown) capable of controlling on/off timing of each switching signal S1 to S4.

A plurality of non-volatile memory cells embodied in each array 11-1 to 11-6 where each portion of the page may be written or where each portion of the page may be read may be designated by decoding row addresses and column addresses. Accordingly, a memory device 10 according to various embodiments of the present invention may further include a row decoder (not shown) for decoding the row addresses and a column decoder or a Y-decoder illustrated in FIG. 3 for decoding the column addresses.

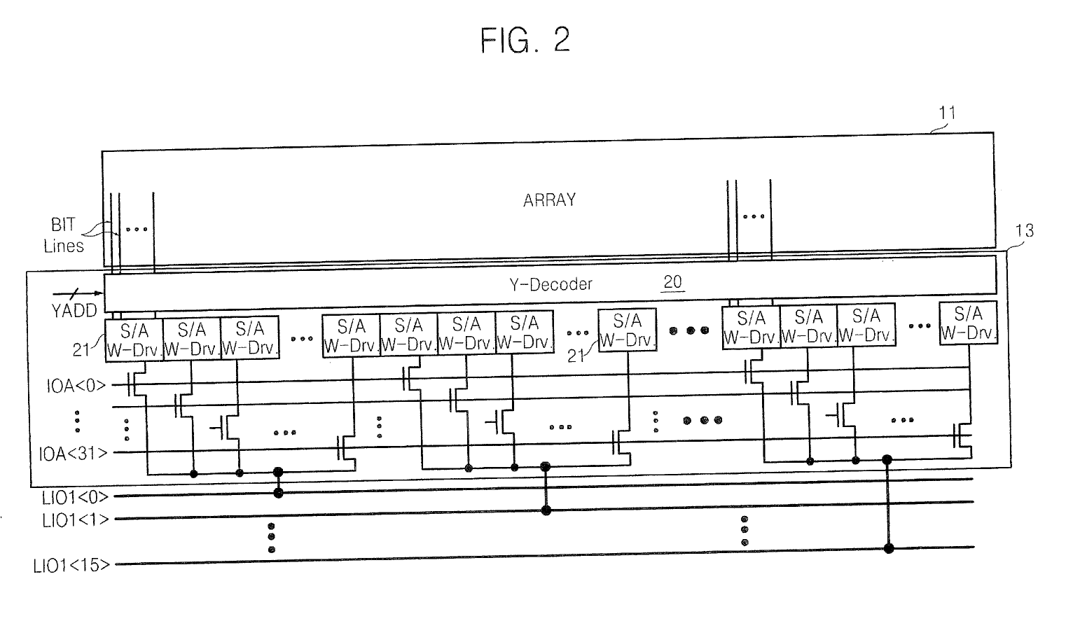

FIG. 2 shows a circuit diagram of a write/read circuit illustrated in FIG. 1. FIG. 2 illustrates a write/read circuit 13, an array 11, and a first data bus 15-1 for an ease of explanation. A write/read circuit 13 for processing a 1/N of a page may include a Y-decoder 20, a plurality of write drivers/sense amplifiers 21, and a plurality of selection circuits.

When a page P is 1 KByte and the number NA of arrays embodied in the memory device 10 is 16, a size SZ of a write/read circuit is 64 Bytes. Thus, the write/read circuit 13 for processing a 1/16 of the page may be connected to a plurality of bit lines, e.g., 512 (=29) bit lines. The Y decoder 20 may select a plurality of bit lines by decoding column addresses YADD input from outside (i.e., from external of the device.).

A plurality of write drivers/sense amplifiers 21 may transmit a part of a portion of a page to be written to a plurality of bit lines selected by the Y decoder 20 or sense and amplify a part of a portion of a page to be read from the plurality of bit lines, respectively.

For example, a plurality of selection circuits may connect/disconnect each of a plurality of input/output lines LIO1<0:15> and each of a plurality of write drivers/sense amplifiers 21, which configure a first data bus 15-1, in response to input/output line addresses IOA<0:31>. The plurality of selection circuits may be embodied as a MOSFET. Accordingly, each write driver/sense amplifier 21 may write data input through each of the plurality of input/output lines LIO1<0:15> to each non-volatile memory of an array 11 during a write operation.

Moreover, each write driver/sense amplifier 21 may transmit each data read from each non-volatile memory of the array 11 to each of the plurality of input/output lines LIO1<0:15> after sensing and amplifying it.

FIG. 3 shows a circuit diagram of a first switching circuit illustrated in FIG. 1. Referring to FIGS. 1 and 3, a plurality of switches SW0 to SW15 embodied in a first switching circuit 19-1 may connect/disconnect a first data bus 15-1 and a second data bus 17 arranged in a first row.

For example, the plurality of switches SW0 to SW15 may be embodied as a MOSFET, e.g., an NMOSFET or a PMOSFET, as illustrated in FIG. 3, respectively. Moreover, the plurality of switches SW0 to SW15 may be embodied as a transmission gate respectively according to embodiments.

The plurality of switches SW0 to SW15 may connect/disconnect each signal line LIO1<0>, LIO1<1>, . . . LIO1<15> and each signal line GIO<0>, GIO<1>, . . . GIO<15> in response to a first switching signal S1, respectively.

A structure of each switching circuit 19-1 to 19-4 illustrated in FIG. 1 can be substantially the same as a structure of a first switch circuit illustrated in FIG. 3. A plurality of switches embodied in a second switch circuit 19-2 may connect/disconnect a first data bus 15-2 and a second data bus 17 arranged in a second row in response to a second switching signal S2. A plurality of switches embodied in a third switch circuit 19-3 may connect/disconnect a first data bus 15-3 and a second data bus 17 arranged in a third row in response to a third switching signal S3. Additionally, a plurality of switches embodied in a fourth switching circuit 19-4 may connect/disconnect a first data bus 15-4 and a second data bus 17 arranged in a fourth row in response to a fourth switching signal S4.

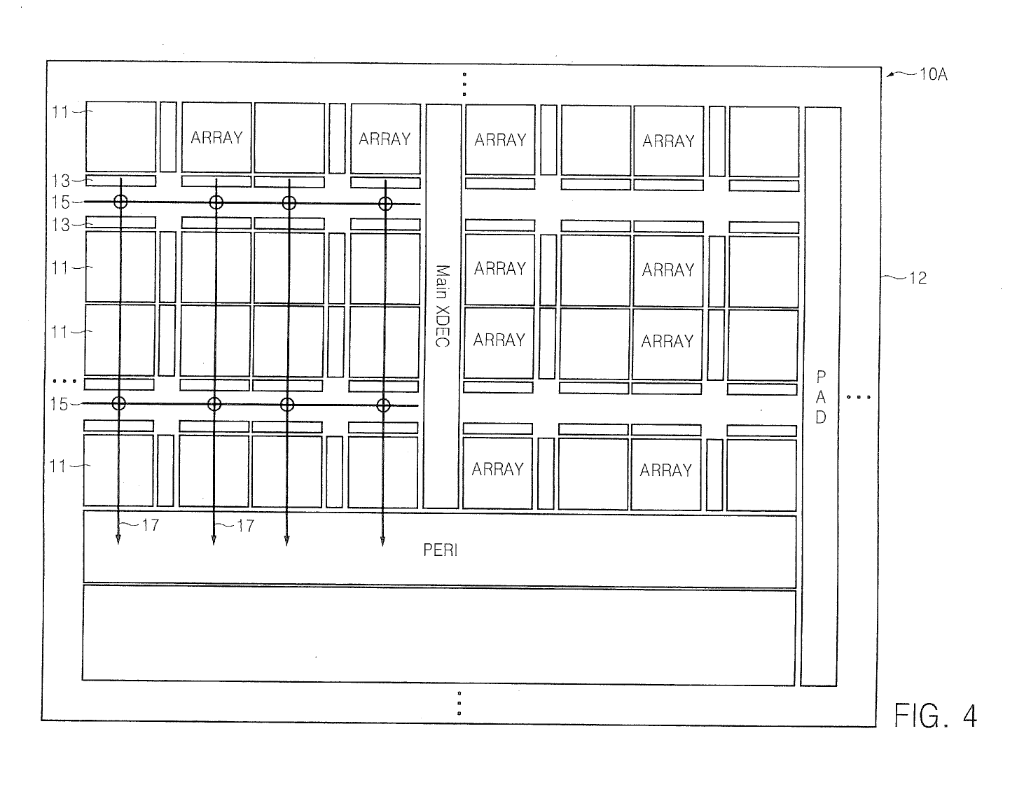

FIG. 4 shows a block diagram of a memory device according to other embodiments of the present invention.

Referring to FIG. 4, centering around a region where a peripheral circuit PERI is arranged, an upper region and a lower region are symmetrical each other. A plurality of arrays 11 and a plurality of write/read circuits 13 are arranged in the upper region. The number of the plurality of arrays 11 and the number of the plurality of write/read circuits 13 are the same.

The second data bus 17 illustrated in FIG. 4, differently from the data bus 17 of FIG. 1, is routed over a plurality of arrays in a bit line direction.

A circle illustrated in FIG. 4 represents a switching circuit as illustrated in FIG. 3. Accordingly, each switching circuit connects/disconnects each first data bus 15 and each second data bus 17 in response to each switching signal. Except for a routing method of each first data bus 15 and each second data bus 17, a method that a memory device 10A processes each portion of a page illustrated in FIG. 4 is substantially the same as a method that a memory device 10 processes each portion of a page illustrated in FIG. 1. That is each write/read circuit 13 may process a 1/N of a page and each array 11 may store a 1/N of the page.

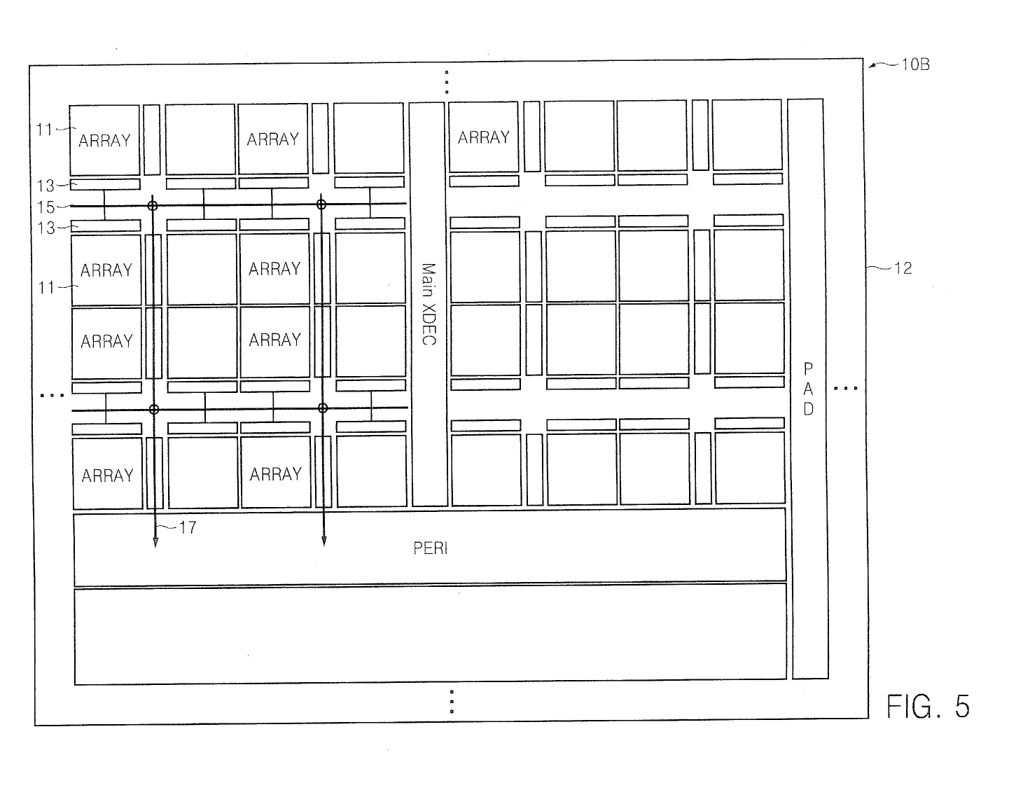

FIG. 5 shows a block diagram of a memory device according to other embodiments of the present invention. Referring to FIG. 5, centering around a region where a peripheral circuit PERI is arranged, an upper region and a lower region are symmetrical each other. A plurality of arrays 11 and a plurality of write/read circuits 13 are arranged in the upper region. The number of the plurality of arrays 11 and the number of the plurality of write/read circuits 13 are the same.

A second data bus 17 illustrated in FIG. 5, differently from a second data bus 17 of FIG. 1, is routed over a region where a sub word line decoder is embodied in a bit line direction. When a plurality of arrays are arranged in three-dimension, the number of signal lines, e.g., metal lines, used to input/output a page is increased. Thus, a method of routing the second data bus 17 over a region where the sub word line decoder is embodied may use space efficiently.

A circle illustrated in FIG. 5 represents a switching circuit as illustrated in FIG. 3. Accordingly, each switching circuit connects/disconnects each first data bus 15 and each second data bus 17 in response to each switching signal. Except for a routing method of each first data bus 15 and each second data bus 17, a method that a memory device 10B illustrated in FIG. 5 processes each portion of a page is substantially the same as a method that a memory device 10 illustrated in FIG. 1 processes each portion of a page.

That is, each write/read circuit 13 may process a 1/N of the page and each array 11 may store a 1/N of the page.

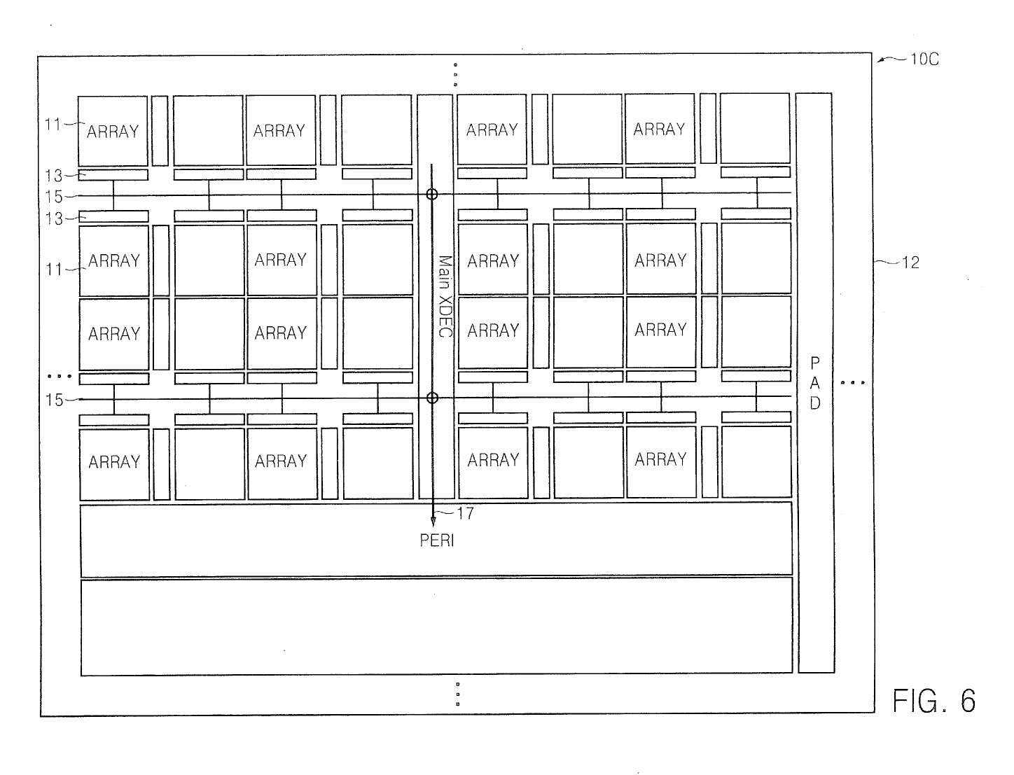

FIG. 6 shows a block diagram of a memory device according to other embodiments of the present invention. Referring to FIG. 6, centering around a region where a peripheral circuit PERI is arranged, an upper region and a lower region are symmetrical to each other. A plurality of arrays 11, a plurality of write/read circuits 13, and a main decoder are arranged in the upper region. The number of the plurality of arrays 11 and the number of the plurality of write/read circuits 13 are the same.

A second data bus 17 illustrated in FIG. 6, differently from a second data bus 17 illustrated in FIG. 1, is routed over a region where a main word line decoder Main XDEC is embodied in a bit line direction. A circle illustrated in FIG. 6 represents a switching circuit as illustrated in FIG. 3. Accordingly, each switching circuit connects/disconnects each first data bus 15 and each second data bus 17 in response to each switching signal.

Except for a routing method of each first data bus 15 and each second data bus 17, a method that a memory device 10C illustrated in FIG. 6 processes each portion of a page is substantially the same as a method that a memory device 10 illustrated in FIG. 1 processes each portion of a page. That is, each write/read circuit 13 may process a 1/N of a page and each array 11 may store a 1/N of the page.

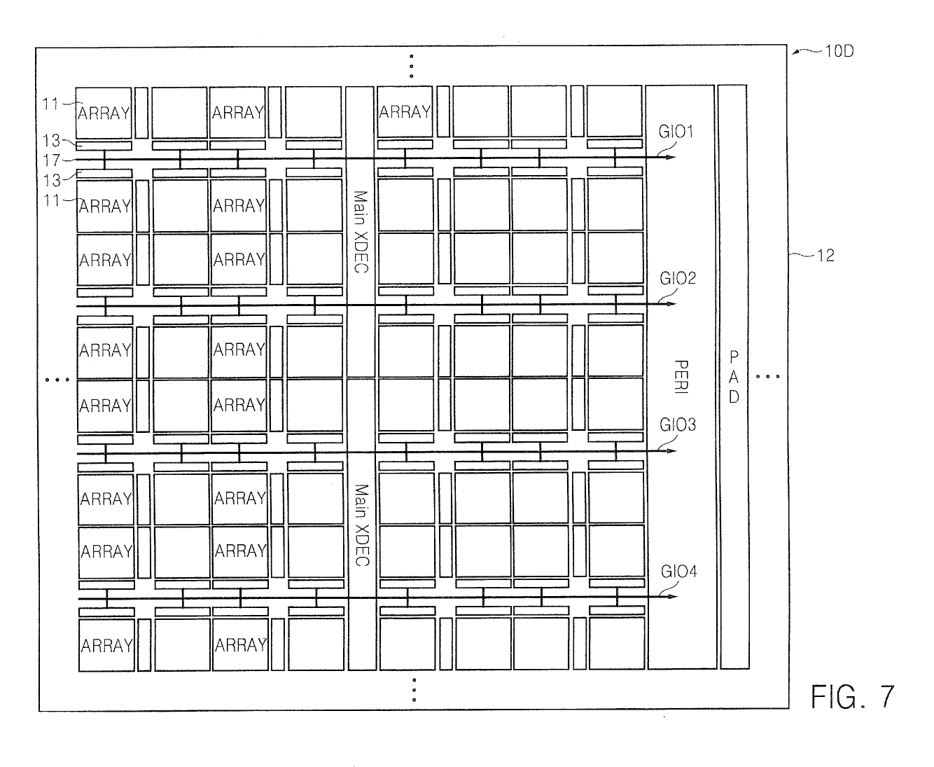

FIG. 7 shows a block diagram of a memory device according to other embodiments of the present invention. Referring to FIG. 7, a memory device 10D includes a plurality of arrays 11, a plurality of write/read circuits 13, and a plurality of main decoders. The number of the plurality of arrays 11 and the number of the plurality of write/read circuits are the same.

A second data bus 17 of FIG. 7, differently from a second data bus 17 of FIG. 1, is routed to a peripheral region, passing in a row direction over a region where a main word line decoder Main XDEC is embodied.

Each switching circuit (not shown) connects/disconnects each first data bus 15 and each second data bus GIO1, GIO2, GIO3, and GIO4 in response to each switching signal. Except for a routing method of each first data bus 15 and each second data bus GIO1, GIO2, GIO3, and GIO4, a method that a memory device 10D illustrated in FIG. 7 processes each portion of a page is substantially the same as a method that a memory device 10 of FIG. 1 processes each portion of a page. That is, each write/read circuit 13 may process a 1/N of a page and each array 11 may store a 1/N of the page.

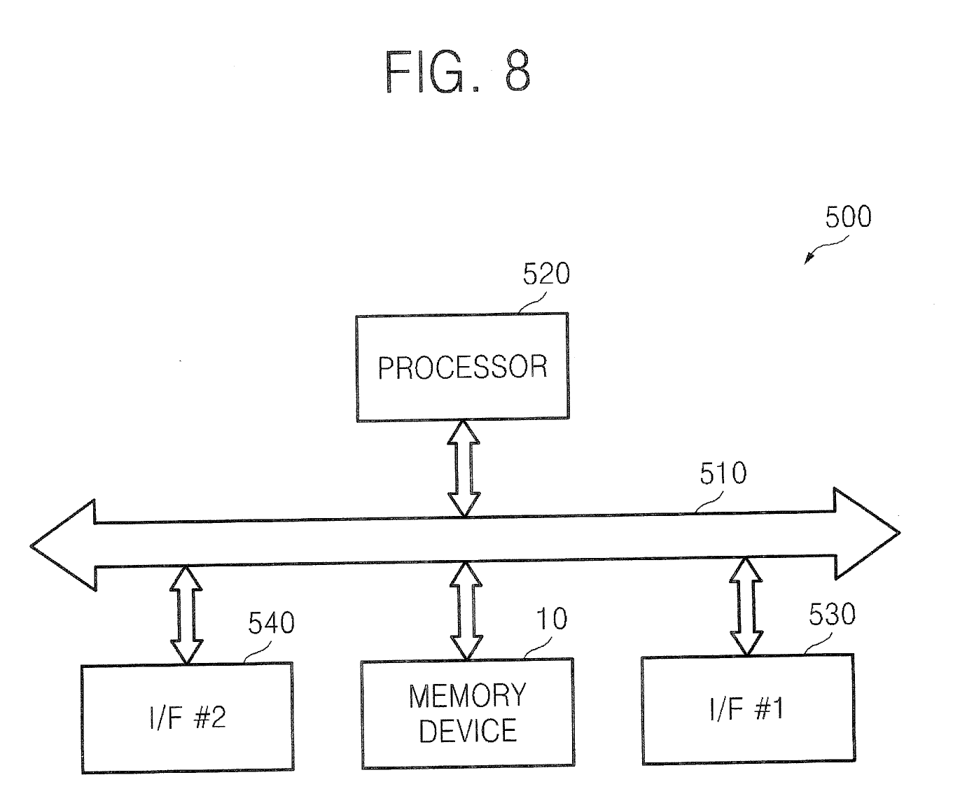

FIG. 8 shows a block diagram of a memory system including a memory device according to various embodiments of the present invention. Referring to FIG. 8, a memory system 500 may include each memory device 10, 10A, 10B, 10C, and/or 10D, which are all called 10, and a processor 520. The memory system 500 may include all electronic devices including a memory device 10 capable of storing data and a processor 520 capable of processing data stored or to be stored in the memory device 10.

For example, the memory system 500 may include handheld devices such as a mobile phone, a MPEG Audio Layer-3 MP3 player, a MPEG Audio Layer-4 MP4 player, a Personal Digital Assistants (PDA), or a Portable Media Player (PMP). The memory system 500 may include a data processing system such as a personal computer (PC), a notebook-sized personal computer or a laptop computer.

Additionally, the memory system 500 may include a memory card such as a secure digital (SD) card or multi media card (MMC). The memory system 500 may include a smart card. The memory system 500 may include a solid state drive (SSD). According to various embodiments, the memory device 10 and the processor 520 may be embodied as a chip, e.g., a system on chip (SoC), or additional independent devices.

The memory system 500 may further include a first interface logic 530 connected to a data bus 510. For example, the first interface logic 530 may be an input/output device. Accordingly, the processor 520 may process and write data input through the first interface logic 530 to the memory device 10, and may read data stored in the memory device 10 and output it to outside through the first interface logic 530. The memory system 500 may exchange data with other hardware or other software through the first interface logic 530.

The memory system 500 may further include a second interface logic 540 connected to the data bus 510. The second interface logic 540 may be an interface logic for wireless communication. The second interface logic 540 may be embodied as software or a firmware. Accordingly, the second interface logic 540 receives and processes, e.g., decodes and/or corrects an error code, a radio signal according to wireless protocol, and transmits processed data to the processor 520. And then, the processor 520 may write data output from the second interface logic 540 to the memory device 10 or transmit it to outside through the first interface logic 530.

In addition, when the processor 520 reads data stored in the memory device 10 and transmits the read data to the second interface logic 540, the second interface logic 540 may convert data transmitted from the processor 520 according to wireless protocol and transmit a converted radio signal to outside.

When the memory system 500 is embodied as an image pick-up device or an image capture device, the memory system 500 may further include an image sensor (not shown). The image sensor may be a CMOS image sensor using a CMOS process. In this case, the image sensor may convert an optical signal to an electric signal, generate data from a converted electric signal, and transmit generated data to the processor 520. Here, the processor 520 may store data transmitted from an image sensor to the memory device 10 or transmit the data to outside through the first interface logic 530 and/or the second interface logic 540.

As described above, the memory device 10 may process data output from the processor 520 by page according to an order output from the processor 520. In addition, the memory device 10 may read data by page according to an order output from the processor 520 and transmit a read page to the processor 520. A method in which the memory device 10 processes data by page is the same as what is explained referring to FIGS. 1 to 7.

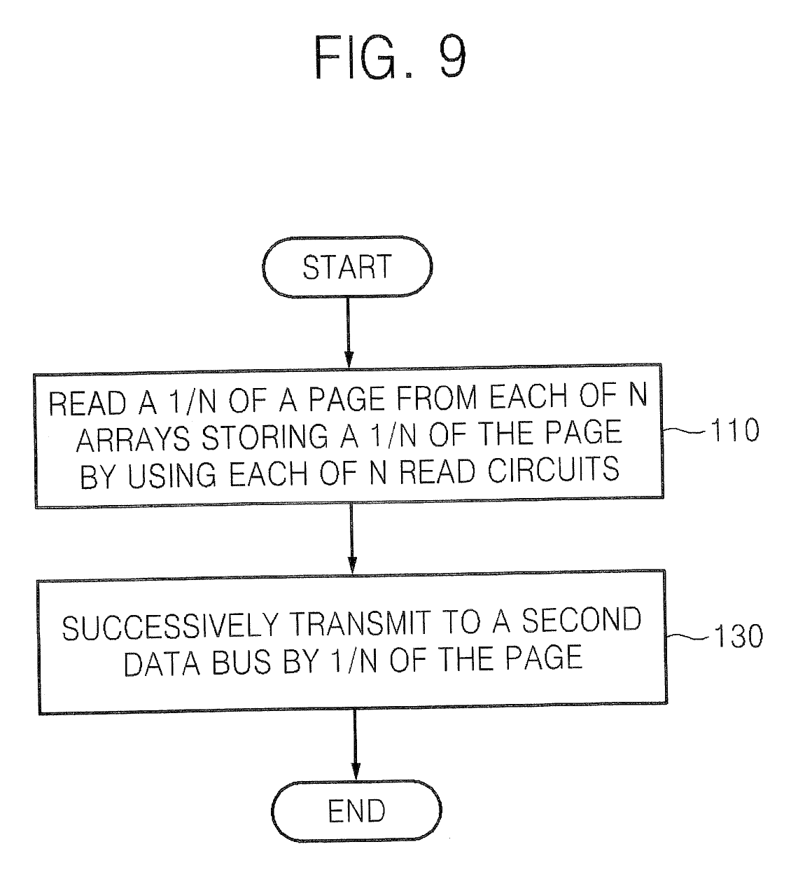

FIG. 9 shows a data processing method of a data processing device according to various embodiments of the present invention. Referring to FIGS. 1 to 9, a data read operation is explained as follows. A memory device 10 reads a 1/N of a page from each of N arrays storing a 1/N of the page by using each of N read circuits (110). To output the page to outside, a 1/N of the page read by each of the N read circuits is successively transmitted to a second data bus (130).

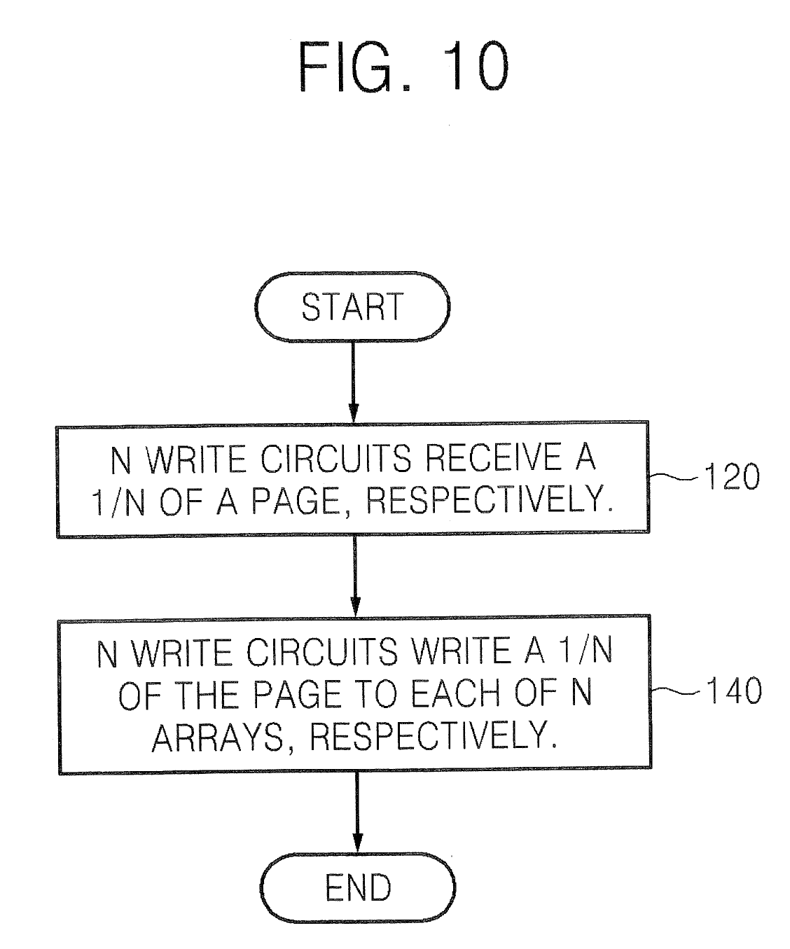

FIG. 10 shows a data processing method of a data processing device according to other embodiments of the present invention. Referring to FIGS. 1 to 9, a data write operation is explained as follows. N write circuits receive a 1/N of a page, respectively (120). The N write circuits write a 1/N of the page to each of N arrays, respectively (140).

A memory device 40 or a memory system 500 including the memory device 40 and a processor 520 according to embodiments of the present invention may be embodied as a package such as Package On Package (POP), Ball Grid Arrays (BGAs), Chip Scale Packages (CSPs), Plastic Leaded Chip Carrier (PLCC), Plastic Dual In-Line Package (PDIP), Die in Waffle Pack, Din in Wafer Form, Chip On Board (COB), CERamic Dual In-Line Package (CERDIP), plastic metric quad flat pack (MQFP), Thin Quad Flat Pack (TQFP), Small outline (SOIC), Shrink small outline package (SSOP), thin small outline (TSOP), system in package (SIP), multi chip package (MCP), wafer-level fabricated package (WFP), or wafer-level processed stack package (WSP) and so on.

A memory device of the present invention may reduce bit line R/C loading since it may disperse and arrange each write/read circuits at one side of each array. Additionally, a memory device of the present invention may increase performance of the memory device since it may increase amount of data which may pre-fetch at once by using each write/read circuit. A memory device of the present invention may also reduce process cost since it may reduce the number of global signal lines.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

1. A memory device comprising:
N arrays, a respective one of which is configured to store 1/N of a page; and
N write/read circuits, where N is a natural number, a respective one of which is adjacent a respective one of the N arrays, and is configured to write/read the 1/N of the page to/from the adjacent one of the N arrays.

2. The memory device of claim 1, further comprising a semiconductor substrate, wherein the N arrays and the N write/read circuits are arranged in the semiconductor substrate to provide an integrated circuit memory device.

3. The memory device of claim 2, wherein the N array is a first group of N arrays and the N write/read circuits is a first group of N write/read circuits, the memory device further comprising:
a second group of N arrays arranged in the semiconductor substrate, a respective one of which is configured to store 1/N of a page; and
a second group of N write/read circuits, a respective one of which is adjacent a respective one of the N arrays in the second group, and is configured to write/read the 1/N of the page to/from the adjacent one of the N arrays.

4. The memory device of claim 2, wherein the N arrays are arranged in the semiconductor substrate by being separated from each other and the respective N write/read circuits are arranged at one side of a respective one of the N arrays.

5. The memory device of claim 1, wherein the N arrays are enabled simultaneously or sequentially, respectively, and the N write/read circuits are enabled simultaneously or sequentially, respectively.

6. The memory device of claim 1, wherein the N arrays are enabled by M arrays, wherein M is a natural number and smaller than N, and the N write/read circuits are enabled by M write/read circuits.

7. The memory device of claim 1, wherein the N arrays include a plurality of non-volatile memory cells.

8. The memory device of claim 1, wherein the N arrays include a plurality of resistive memory cells.

9. The memory device of claim 1, wherein the N is determined by dividing a density of the memory device by a density of the N arrays.

10. The memory device of claim 1, wherein the N arrays are arranged in a two-dimensional matrix form and the N write/read circuits are arranged at one side of each of the N arrays, respectively,
wherein the memory device further comprises:
a plurality of first data buses, a respective one of which is connected to a respective plurality of write/read circuits arranged in the first direction;
a second data bus arranged in a second direction which is perpendicular to the first direction; and
a plurality of switching circuits, a respective one of which is connected between a respective one of the plurality of first data buses and the second data bus.

11. The memory device of claim 10, wherein the plurality of the switching circuits connect each of the plurality of first data buses to the second data bus successively in response to a corresponding switching signal among a plurality of switching signals, respectively.

12. The memory device of claim 10, wherein the second data bus is routed over a plurality of arrays arranged in the second direction.

13. The memory device of claim 10, wherein the second data bus is routed at one side of a plurality of arrays arranged in the second direction.

14. A memory device comprising:
N arrays respectively including a plurality of word lines, a plurality of bit lines, and a plurality of non-volatile memory cells connected between the plurality of word lines and the plurality of bit lines; and
N write/read circuits, a respective one of which is connected to a respective one of the N non-volatile memory arrays,
wherein a number of the plurality of bit lines connected to each of the N write/read circuits corresponds to a value calculated by dividing a page of the memory device by the N.

15. The memory device of claim 14, further comprising a semiconductor substrate, wherein the N arrays and the N write/read circuits are arranged in the semiconductor substrate to provide an integrated circuit memory device.

16. The memory device of claim 15, wherein the N arrays is a first group of N arrays and the N write/read circuits is a first group of N write/read circuits, the memory device further comprising:
a second group of N arrays respectively including a plurality of word lines, a plurality of bit lines, and a plurality of non-volatile memory cells connected between the plurality of word lines and the plurality of bit lines, and arranged in the semiconductor substrate; and
a second group of N read/write circuits, a respective one of which is connected to a respective one of the second group of N non-volatile memory arrays, and is arranged in the semiconductor substrate.

17. The memory device of claim 14, wherein the N arrays are arranged in a two-dimensional matrix form,
wherein the memory device further comprises:
a plurality of first data buses, a respective one of which is connected to a respective plurality of write/read circuits arranged in a first direction;
a second data bus arranged in a second direction which is perpendicular to the first direction; and
a plurality of switching circuits, a respective one of which is connected between a respective one of the plurality of first data buses and the second data bus.

18. (canceled)

19. A memory system comprising:
the memory device of claim 1; and
a processor connected to the memory device and controlling writing/reading a page to/from the memory device by page.

20. The memory system of claim 19 further comprising a semiconductor substrate, wherein the N arrays and the N write/read circuits are arranged in the semiconductor substrate to provide an integrated circuit memory device.

21. The memory system of claim 20, wherein the N array is a first group of N arrays and the N write/read circuits is a first group of N write/read circuits, the memory device further comprising:
a second group of N arrays arranged in the semiconductor substrate, a respective one of which is configured to store 1/N of a page; and
a second group of N write/read circuits, a respective one of which is adjacent a respective one of the N arrays in the second group, and is configured to write/read the 1/N of the page to/from the adjacent one of the N arrays.

22. The memory system of claim 19, wherein the N arrays are arranged in a two-dimensional matrix form and the N write/read circuits are arranged in a first direction at one side of each of the N arrays, respectively,
wherein the memory device further comprises:
a plurality of first data buses, a respective one of which is connected to a respective plurality of write/read circuits respectively arranged in the first direction;
a second data bus arranged in a second direction which is perpendicular to the first direction; and
a plurality of switching circuits, a respective one of which is connected between a respective one of the plurality of first data buses and the second data bus.

23. (canceled)

24. A memory system comprising:
memory device of claim 14; and
a processor connected to the memory device and controlling writing or reading a page to/from the memory device by unit of page.

25. The memory system of claim 24 further comprising a semiconductor substrate, wherein the N arrays and the N write/read circuits are arranged in the semiconductor substrate to provide an integrated circuit memory device.

26. The memory system of claim 25, wherein the N arrays is a first group of N arrays and the N write/read circuits is a first group of N write/read circuits, the memory device further comprising:
a second group of N arrays respectively including a plurality of word lines, a plurality of bit lines, and a plurality of non-volatile memory cells connected between the plurality of word lines and the plurality of bit lines, and arranged in the semiconductor substrate; and
a second group of N read/write circuits, a respective one of which is connected to a respective one of the second group of N non-volatile memory arrays, and is arranged in the semiconductor substrate.

27. The memory system of claim 27, wherein the N arrays are arranged in a two-dimensional matrix form,
wherein the memory device further comprises:
a plurality of first data buses, a respective one of which is connected to a respective plurality of write/read circuits arranged in a first direction;
a second data bus arranged in a second direction which is perpendicular to the first direction; and
a plurality of switching circuits, a respective one of which is connected between a respective one of the plurality of first data buses and the second data bus.

28-30. (canceled)
